(19) United States
(12) Patent Application Publication
(10) Pub. No.: US 2005/0051421 A1
(43) Pub. Date: Mar. 10, 2005

(54) Process designed to prevent deposition of contaminating particles on the surface of a micro-component, micro-component storage device and thin layer deposition device

(75) Inventors: Etienne Quesnel, Meylan (FR); Viviane Muffato, Le Gua (FR)

Correspondence Address: OLIFF & BERRIDGE, PLC, P.O. BOX 19928, ALEXANDRIA, VA, 22320, US

(73) Assignee: Commissariat a I'Energie Atomique, Paris (FR)

(21) Appl. No.: 10/816,911

(22) Filed: Apr. 5, 2004

(30) Foreign Application Priority Data
Apr. 28, 2003 (FR) 03 05169

(51) Int. Cl. C23C 14/00

(52) U.S. Cl. 204/192.12; 204/298.02

(57) ABSTRACT

A process designed to prevent deposition of polarized contaminating particles on the surface of a micro-component consists, according to the invention, in sputtering a beam of particles between the contamination source and the micro-component. At least a part of the particles of the beam has an opposite polarity from that of the contaminating particles. The beam of particles is preferably a plasma and is designed to drag the contaminating particles away from the free surface of the micro-component to a collecting element. The invention also relates to a micro-component storage device and a thin layer deposition device respectively implementing such a process.

### BACKGROUND OF THE INVENTION

The invention relates to a process designed to prevent deposition of polarized first particles originating from at least one contamination source on the free surface of a micro-component arranged in a vacuum chamber.

The invention also relates to a storage device implementing such a process and comprising a vacuum chamber wherein there is arranged at least one micro-component.

The invention also relates to a thin layer deposition device implementing such a process and comprising a vacuum chamber wherein there is arranged a micro-component comprising at least one substrate and means for sputtering a flow of matter designed to form at least one thin layer on the surface of the micro-component.

### STATE OF THE ART

Thin layers used in particular in optical or mechanical applications must comprise a limited number of defects and the tolerated defects must have a critical size. The defects formed in a thin layer can in fact degrade the layer in operation or even prevent functioning thereof. Thus, in layers having a mechanical function such as anti-wear, anti-corrosion or lubricating layers, defects constitute weakness points which may give rise to wear of the layer.

Likewise, the defects formed in optical layers can generate malfunctions. For example, a lithography mask used in the Extreme Ultraviolet (EUV), in a wavelength range comprised between 10 nm and 20 nm, comprises a substrate whereon a plurality of superposed layers are successively deposited forming a reflector, a protective layer, then a buffer layer and an absorbent layer. Patterns are etched in the buffer layer and absorbent layer to then be imaged on a silicon wafer to be insulated to form a printed circuit. The defects present on the surface of the mask or in the first layers of the reflector are liable to disturb the image of the projected pattern. This disturbance may create breaks in the tracks or defects in the circuit patterns at the level of the printed circuit, on the silicon.

Moreover, the size of the defects also plays a critical role in EUV lithography masks. EUV lithography projection systems in fact operate with an optical reduction factor 4. Thus, to achieve printed circuits having critical dimensions of 30 nm to 50 nm, the size of the patterns formed in the absorbent layer and in the buffer layer must be comprised between 120 nm and 200 nm. The mask must therefore not contain defects having a diameter greater than 50 nm.

A part of the defects of thin layers is more often than not formed by contaminating particles that were generated in the course of the thin layer deposition process, for example during a vacuum evaporation process, or that were deposited on the surface of a micro-component when the latter was stored. For example, for an EUV lithography mask, the realization of the reflector is the critical step, i.e. deposition of the superposed thin layers, generally made of molybdenum and silicon, forming the reflector. The reflector generally requires a rate of defects with a size larger than 50 nm of less than 0.003 defects per cm². However deposition techniques of the thin layers forming the reflector are known to generate defects. Indeed, even the Ion Beam Sputtering (IBS) deposition technique generally used to achieve the reflector of an EUV mask is not satisfactory. As the sputtering source itself generates contaminating particles having a size smaller than 150 nm, it is in fact extremely difficult to limit the defect densities to the imposed level and in reproducible manner.

C. C. Walton et al, in the article “Extreme Ultraviolet Lithography-reflective mask technology” (Emerging Lithography Technologies IV, Proceedings of SPIE, vol 3997, 2000, pages 496-507) proposed changes in the IBS process designed to achieve deposition of thin layers designed to form the reflector of an EUV lithography mask. Thus, to reduce the defects and improve deposition devices, they propose to mechanically polish and etch the molybdenum and silicon sputtering targets, to fit metal screens on the ion gun and on the walls of the chamber, to fit a rigid linear system in the deposition system to provide a capture surface for the stray particles originating from the sputtering target, and so on. These modifications do not however enable the required defect rates for EUV lithography masks to be obtained in reproducible manner.

### OBJECT OF THE INVENTION

One object of the invention is to reduce the risk of contaminating the free surface of a micro-component arranged in a vacuum chamber, by deposition of parasite particles, in an efficient, simple and reproducible manner.

According to the invention, this object is achieved by the fact that the process consists in sputtering a beam of second particles between the contamination source and the micro-component, at least a part of which second particles has an opposite polarity from that of the first particles, so as to drag the first particles away from the micro-component to a collecting element.

According to a development of the invention, the beam of second particles is a plasma.

According to a preferred embodiment, the micro-component comprises a substrate whereon at least one thin layer is designed to be deposited, and the first particles are dragged by a flow of sputtered matter designed to form said thin layer, the beam of second particles passing through the flow of sputtered matter upstream from the micro-component.

According to another feature of the invention, the flow of sputtered matter is formed by bombardment of a target by a sputtering plasma, the beam of second particles being able to pass simultaneously through the sputtering plasma and the flow of sputtered matter.

Another object of the invention is to achieve a storage device designed to store at least one micro-component, protecting the surface thereof efficiently and simply from a possible deposition of contaminating particles.

According to the invention, this object is achieved by the fact that the device comprises a source emitting the beam of second particles parallel to and near the free surface of the micro-component.

Another object of the invention is to achieve a thin layer deposition device efficiently limiting the risk of contamination of the thin layer by deposition of contaminating particles.

According to the invention, this object is achieved by the fact that the thin layer deposition device comprises a source emitting the beam of second particles in the direction of the flow of matter so that it drags the first particles contained in the flow away from the micro-component.

### DESCRIPTION OF THE DRAWINGS

Other advantages and features will become more clearly apparent from the following description of particular embodiments of the invention given as non-restrictive examples only and represented in the accompanying drawings, in which:

FIG. 1 schematically represents a first embodiment of a thin layer deposition device according to the invention.

FIG. 2 represents a second embodiment of a thin layer deposition device according to the invention.

FIG. 3 represents an alternative embodiment of the thin layer deposition device according to FIG. 2.

FIG. 4 schematically represents a particular embodiment of a storage device according to the invention.

### DETAILED DESCRIPTION OF PARTICULAR EMBODIMENTS

According to the invention, a process designed to prevent deposition of polarized contaminating particles originating from a contamination source on the free surface of a micro-component consists in sputtering a beam of particles at least a part whereof has an opposite polarity from that of the contaminating particles. The micro-component is arranged in the vacuum chamber. The beam of particles is sputtered between the contamination source and the micro-component and is designed to drag the contaminating particles away from the micro-component to a collecting element. The beam of particles is preferably a plasma.

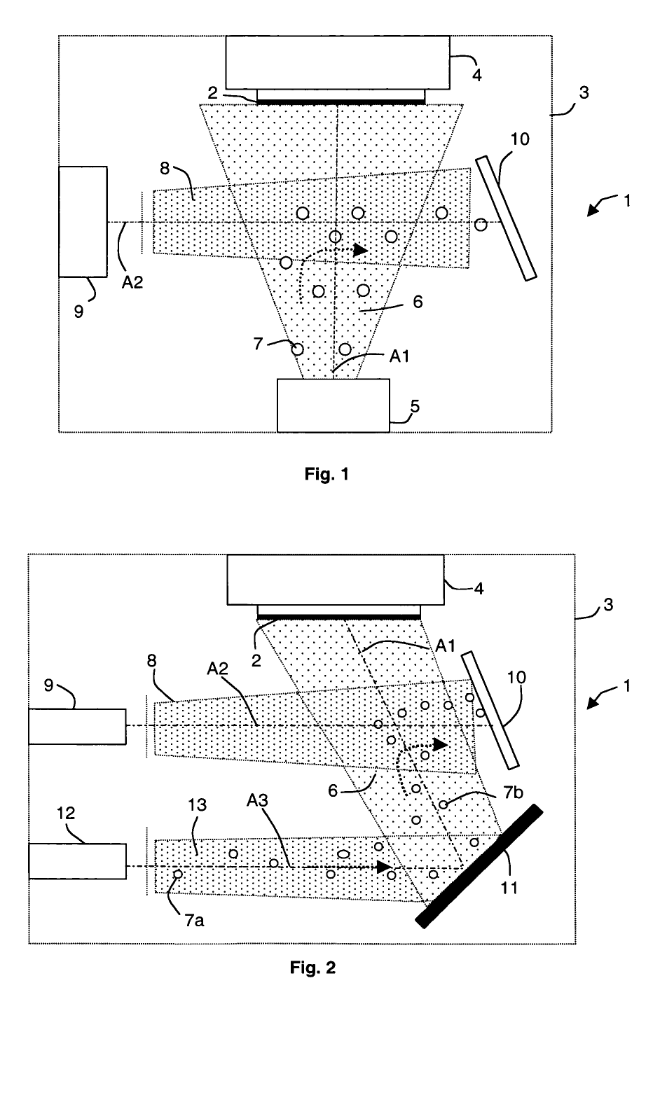

Thus, according to FIG. 1, a device 1 implementing such a process is designed to deposit at least one thin layer on a substrate 2 so as to form a micro-component. The device 1 comprises a vacuum chamber 3 wherein there are respectively deposited, on two opposite walls, a substrate holder 4 comprising the substrate 2 and a source 5 designed to sputter a flow 6 of atomic or molecular matter along an axis Al in the direction of the free surface of the substrate 2. The sputtered matter is designed to form a thin layer on the free surface of the substrate.

The source 5 can be of any type depending on the deposition process used. Thus, it can for example be a cathodic sputtering cathode in the case of deposition by cathodic sputtering, a sputtering target in the case of ion beam sputtering (IBS) or a Joule effect evaporation source in the case of deposition by thermal evaporation by Joule effect. The source 5 can also be a source emitting an electron beam or a laser beam or be a source to perform chemical vapor deposition. In operation, the source 5 emits polarized contaminating particles 7 that are dragged along with the flow of sputtered matter and that are liable to contaminate the free surface of the substrate 2.

To prevent contaminating particles 7 from depositing on the free surface of the substrate 2, a beam 8 of particles, originating from an ion source 9, is sputtered along an axis A2 so as to pass through the flow of sputtered matter 6, upstream from the substrate. The axis A2 is perpendicular to the axis Al. At least a part of the particles originating from the ion source 9 has an opposite polarity from that of the contaminating particles 7 so as to drag the contaminating particles 7 to a collecting element 10 arranged on the axis A2, away from the substrate 2. Dragging of the contaminating particles 7 to the collecting plate 10 is represented by a broken arrow in FIG. 1. As the sputtered matter designed to form the thin layer is not polarized, it is not dragged by the beam 8 of particles. It therefore passes through the beam 8 of particles and deposits on the free surface of the substrate to form the thin layer.

The collecting element can for example be a collecting plate and the beam 8 of particles is preferably a plasma formed by positive ions and neutralizing electrons. The proportion of ions and electrons is generally such that the plasma remains globally neutral. However, locally the plasma is not neutral. Thus, the contaminating particles 7 are trapped when passing through the plasma, notably by the drag force exerted by the plasma ions on the contaminating particles 7. This force is of the ballistic type with transfer of quantity of motion of the ions to the contaminating particles 7. As the contaminating particles are charged either positively or negatively, the electrical interaction between the plasma and the contaminating particles 7 also enhances trapping of the contaminating particles 7. The gas or mixture of gases coming from the ion source 9 and forming the plasma are preferably chosen from light gases such as neon, helium, hydrogen or other rare gases such as argon or xenon. Thus, the generated plasma does not induce an additional contamination when sputtering of the collecting element 10 is performed. Likewise, to prevent such a contamination, the ion extraction voltage applied to the ion source, i.e. the voltage designed to generate the plasma, is preferably comprised between 50 Volts and 200 Volts. This enables a low-energy extracted plasma to be obtained. It is also possible to use a high-energy plasma with the collector 10 polarized positively to slow down the incident ions.

The process used to form the first thin layer on the substrate 2 is also used for deposition of successive thin layers. In this case, the beam of particles has to drag the contaminating particles 7 away from the free surface of the micro-component formed by the substrate and the previously formed thin layers. Thus, what is meant by free surface of the micro-component is either the surface of the substrate 2 when a first thin layer deposition is made on the substrate 2 or the free surface of a thin layer already deposited on the substrate 2.

In the case of thin layer deposition by ion beam sputtering (IBS), the flow 6 of sputtered matter is formed by bombardment of a target 11 by a sputtering plasma 12 (FIG. 2). A sputtering gun 12 sputters a sputtering plasma 13 along an axis A3. The sputtering gun does however generate polarized contaminating particles 7a which are then dragged along with the sputtering plasma 13. When the sputtering plasma 13 bombards the target 11, the latter emits a flow 6 of sputtered molecular or atomic matter along the axis A1 in the direction of the substrate 2. The target 11 also generates polarized contaminating particles 7b. The latter are dragged, along with the contaminating particles 7a, in the flow 6 of sputtered matter until the contaminating particles 7a and 7b encounter a plasma 8 originating from an ion source 9 and passing through the flow 6 of sputtered matter.

The plasma 8, forming a screen, drags the contaminating particles away to the collecting element 10 while letting the sputtered matter pass. In FIG. 2, the axis A3 of the sputtering plasma 13 is parallel to the axis A2 of the plasma 8 and the angle—formed by the axes Al and A3 is an acute angle. Dragging of the contaminating particles 7a and 7b is represented, in FIG. 2, by broken arrows. This embodiment is particularly well suited to deposition of thin layers of molybdenum and silicon, such as those that are designed to form the reflector of an EUV lithography mask operating at a wavelength of 13.7 nm.

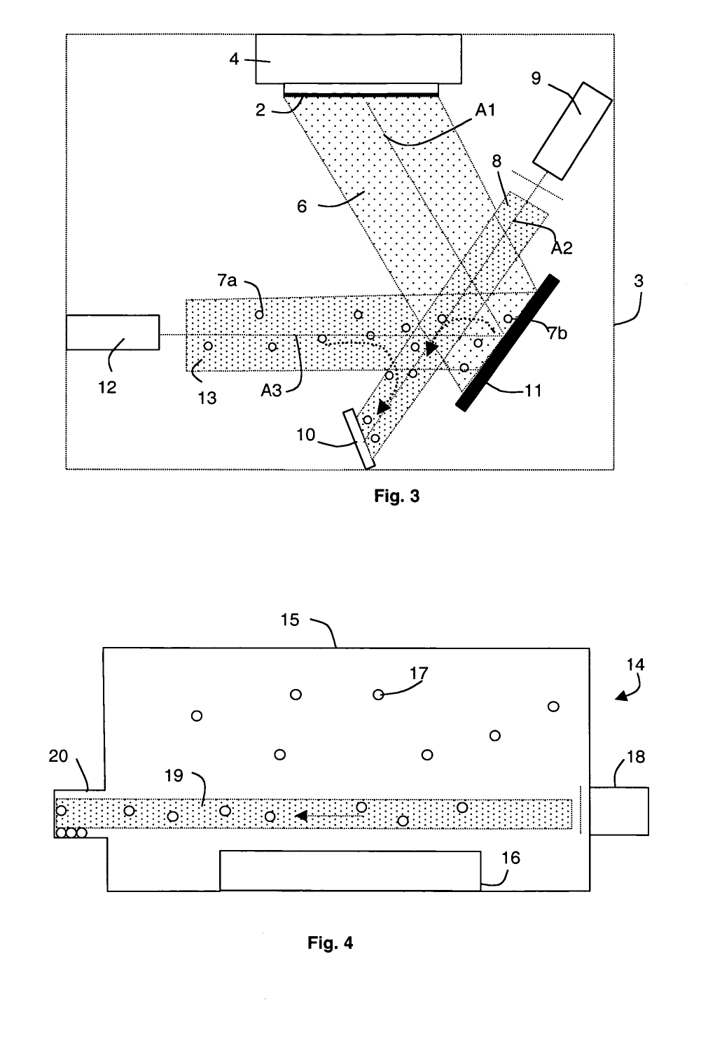

According to an alternative embodiment represented in FIG. 3, the ion source 9 forming the screen plasma 8 can be arranged in such a way that the screen plasma 8 passes simultaneously through the sputtering plasma 13 and the flow 6 of sputtered matter. In this case, the contaminating particles 7a and 7b coming respectively from the sputtering gun 12 and from the target 11 are respectively dragged by the screen plasma 8 according to the arrows represented in broken lines in FIG. 2. The screen plasma 8 passes through the flow 6 of sputtered matter, near the surface of the target 11, so that as soon as the contaminating particles 7b are formed, they are dragged to the collecting element 10 that is located away from the sputtering plasma 13. In this same embodiment, the collecting element 10 is situated away from the substrate 2, which presents the advantage of reducing the risk of contamination due to sputtering of the collecting element 10 by the plasma 8 forming a screen. The invention is not limited to the embodiments described above.

In the embodiment represented in FIG. 2 and in its alternative version represented in FIG. 3, thin layer deposition is performed by IBS. This deposition can also be performed by cathodic sputtering, replacing the target 11 by a sputtering cathode designed to be bombarded by the sputtering plasma 13. The beam 8 of particles can also pass simultaneously through the sputtering plasma 13 and the flow of sputtered matter coming from the sputtering cathode.

Using a beam 8 of polarized particles dragging the contaminating particles away from a micro-component or a substrate enables usual thin layer deposition techniques to be used, while reducing in simple, efficient and reproducible manner the risk of contamination by particles coming from the source generating the matter designed to form the thin layers. This can be applied to any type of micro-component comprising thin layers the number of defects whereof due to the thin layer deposition process has to be very low. Thus, the micro-components can be mirrors used in EUV, optical components with high laser flow resistance, protective layers against environment effects, and in particular anti-corrosion layers, dielectric layers on printed circuits, magnetic layers, resistive layers, etc.

Contamination of a micro-component can also take place when the latter is stored in a vacuum chamber. Indeed, contaminating particles can arise from degassing of the walls of the vacuum chamber. Thus, as represented in FIG. 4, a storage device 14 implementing a process according to the invention comprises a vacuum chamber 15 wherein there is arranged a micro-component 16 which may for example be an EUV lithography mask. The walls of the vacuum chamber 15 give off polarized particles 17 liable to contaminate the free surface of the micro-component 16. To prevent these particles from depositing on the free surface of the micro-component 16, a source 18 emits a beam 19 of particles at least a part whereof has an opposite polarity from that of the contaminating particles 17.

The beam 8 of particles is sputtered parallel to and near the surface of the micro-component 16. The beam 19 of particles is preferably formed by a plasma. Thus, the beam 19 of particles drags the contaminating particles 17 away from the free surface of the micro-component 16 to a collecting element 20, which can be a particle trap. The micro-component 16 can thus be stored in the storage device without any risk of contamination.

1. Process designed to prevent deposition of polarized first particles originating from at least one contamination source on the free surface of a micro-component arranged in a vacuum chamber, process consisting in sputtering a beam of second particles between the contamination source and the micro-component, at least a part of which second particles has an opposite polarity from that of the first particles, so as to drag the first particles away from the micro-component to a collecting element.

2. Process according to claim 1, wherein the beam of second particles is a plasma.

3. Process according to claim 2, wherein the plasma is formed by a gas or a mixture of gases chosen from neon, helium, hydrogen, argon or xenon.

4. Process according to claim 2, wherein the voltage designed to generate the plasma is comprised between 50 Volts and 200 Volts.

5. Process according to claim 1, wherein the micro-component comprises a substrate whereon at least one thin layer is designed to be deposited, and the first particles are dragged by a flow of sputtered matter designed to form said thin layer, the beam of second particles passing through the flow of sputtered matter upstream from the micro-component.

6. Process according to claim 5, wherein the flow of sputtered matter is formed by bombardment of a target by a sputtering plasma.

7. Process according to claim 6, wherein the beam of second particles passes simultaneously through the sputtering plasma and the flow of sputtered matter.

8. Process according to claim 6, wherein deposition of the thin layer is performed by ion beam sputtering.

9. Process according to claim 6, wherein deposition of the thin layer is performed by cathodic sputtering.

10. Process according to claim 5, wherein deposition of the thin layer is performed thermal evaporation by Joule effect.

11. Storage device comprising a vacuum chamber wherein there is arranged at least one micro-component, device comprising a source emitting the beam of second particles parallel to and near the free surface of the micro-component for implementation of the process according to claim 1.

12. Thin layer deposition device comprising a vacuum chamber wherein there is arranged a micro-component comprising at least one substrate and means for sputtering a flow of matter designed to form at least one thin layer on the surface of the micro-component, device comprising a source emitting the beam of second particles in the direction of the flow of matter so that it drags the first particles contained in the flow away from the micro-component, for implementation of the process according to claim 5.
